(19) United States
(12) Patent Application Publication
(10) Pub. No.: US 2025/0159799 A1
(43) Pub. Date: May 15, 2025

(54) WIRING BOARD, ELECTRONIC DEVICE, AND ELECTRONIC MODULE

(71) Applicant: KYOCERA Corporation, Kyoto-shi, Kyoto (JP)

(72) Inventors: Yuki TAKESHIMA, Kirishima-shi (JP); Yoshihiro HOSOI, Kirishima-shi (JP)

(73) Assignee: KYOCERA Corporation, Kyoto-shi, Kyoto (JP)

(21) Appl. No.: 18/839,576

(22) PCT Filed: Feb. 22, 2023
(86) PCT No.: PCT/JP2023/006534

§ 371 Date: Aug. 19, 2024

(30) Foreign Application Priority Data
Feb. 25, 2022 (JP) 2022-027938

(51) Int. Cl. H05K 1/02; H05K 1/18

(52) U.S. Cl. CPC H05K 1/0298; H05K 1/181; H05K 2201/0239

(57) ABSTRACT

A wiring board includes a substrate including a first surface and a second surface positioned on an opposite side from the first surface. The substrate includes a first layer particle positioned on a surface layer on a first surface side, a second layer particle adjacent to the first layer particle on a second surface side, a metal layer positioned at least between the first layer particle and the second layer particle, a first adhesion layer positioned between the first layer particle and the metal layer and in contact with the first layer particle and the metal layer, and a second adhesion layer positioned between the second layer particle and the metal layer and in contact with the second layer particle and the metal layer.

### DESCRIPTION

### Technical Field

The present disclosure is related to a wiring board, an electronic device, and an electronic module.

### Background of Invention

International Publication No. 2008/084867 describes a semiconductor device that includes an insulating film positioned on a semiconductor substrate and a wiring film positioned on the insulating film.

### SUMMARY

### Solution to Problem

In the present disclosure,

a wiring board includes a substrate including a first surface and a second surface positioned on an opposite side from the first surface.

The substrate includes

a first layer particle positioned on a surface layer on a first surface side,

a second layer particle adjacent to the first layer particle on a second surface side,

a metal layer positioned at least between the first layer particle and the second layer particle,

a first adhesion layer positioned between the first layer particle and the metal layer and in contact with the first layer particle and the metal layer, and

a second adhesion layer positioned between the second layer particle and the metal layer and in contact with the second layer particle and the metal layer.

In the present disclosure, an electronic device includes

the above-described wiring board and

the electronic device placed on the wiring board.

In the present disclosure, an electronic module includes

the above-described electronic device and

a module board on which the electronic device is placed.

### BRIEF DESCRIPTION OF THE DRAWINGS

FIG. 1A is a longitudinal sectional view of a wiring board according to an embodiment of the present disclosure.

FIG. 1B is an enlarged longitudinal sectional view of part C1 illustrated in FIG. 1A.

FIG. 1C is an enlarged longitudinal sectional view of part C2 illustrated in FIG. 1A.

FIG. 2 is a diagram illustrating an interlayer structure between a first layer particle and second layer particle.

FIG. 3A is a longitudinal sectional view of a first example illustrating a relationship between first layer particles and a metal layer.

FIG. 3B is a longitudinal sectional view of a second example illustrating a relationship between the first layer particles and the metal layer.

FIG. 3C is a longitudinal sectional view of a third example illustrating a relationship between the first layer particles and the metal layer.

FIG. 3D is a longitudinal sectional view of a fourth example illustrating a relationship between the first layer particles and the metal layer.

FIG. 4A is a longitudinal sectional view of a fifth example illustrating a relationship between the first layer particles and the metal layer.

FIG. 4B is a longitudinal sectional view of a sixth example illustrating a relationship between the first layer particles and the metal layer.

FIG. 4C is a longitudinal sectional view of a seventh example illustrating a relationship between the first layer particles and the metal layer.

FIG. 4D is a longitudinal sectional view of an eighth example illustrating a relationship between the first layer particles and the metal layer.

FIG. 5 is a diagram illustrating an example of a manufacturing method for the wiring board according to the embodiment.

FIG. 6A is a diagram illustrating a state around the first layer particles and second layer particles after a polishing step.

FIG. 6B is a diagram illustrating a state around the first layer particles and the second layer particles in a former stage of a Ti film forming step.

FIG. 6C is a diagram illustrating a state around the first layer particles and the second layer particles after the Ti film forming step.

FIG. 6D is a diagram illustrating a state around the first layer particles and the second layer particles after an electroless plating and sintering step.

FIG. 6E is a diagram illustrating a state around the first layer particles and the second layer particles after removal of a resist.

FIG. 6F is a diagram illustrating a state around the first layer particles and the second layer particles after an etching step.

FIG. 7 is a diagram illustrating an electronic device and an electronic module according to the embodiment of the present disclosure.

### DESCRIPTION OF EMBODIMENTS

Hereinafter, an embodiment of the present disclosure is described in detail with reference to the drawings.

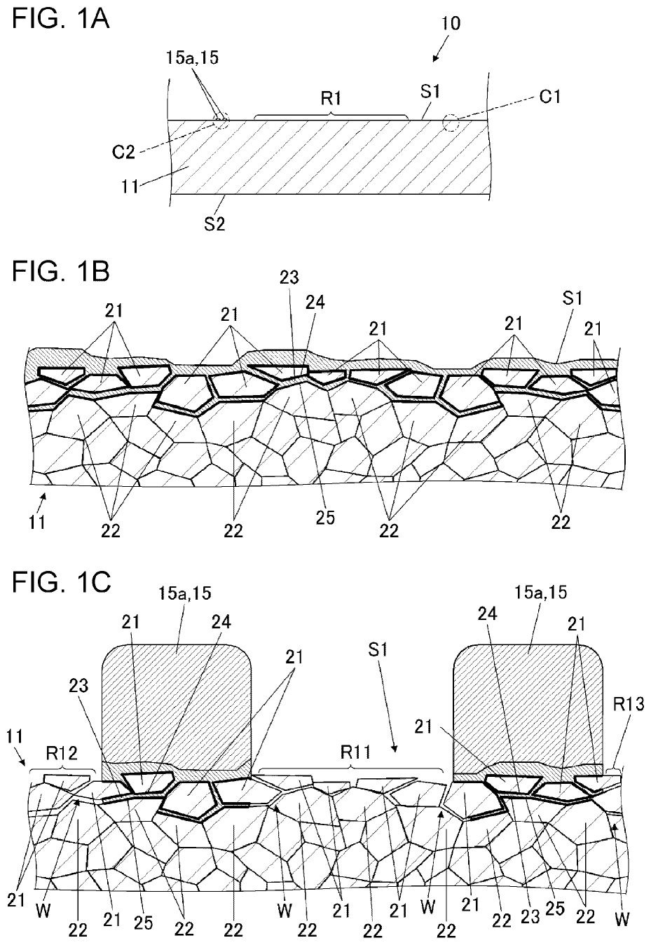

FIG. 1A is a longitudinal sectional view of a wiring board according to the embodiment of the present disclosure. FIG. 1B is an enlarged longitudinal sectional view of part C1 illustrated in FIG. 1A. FIG. 1C is an enlarged longitudinal sectional view of part C2 illustrated in FIG. 1A. In the present embodiment, a wiring board 10 includes a substrate 11 and a wiring conductor 15.

The substrate 11 may include a first surface S1 and a second surface S2 positioned on an opposite side from the first surface S1. The substrate 11 may have a plate shape or a box shape including recesses, steps, or the like. The substrate 11 may include ceramic as a material of the entirety of the substrate 11 or at least a material on the first surface S1 side. A main component of the above-described ceramic may be AlN (aluminum nitride). The main component may be silicon nitride, silicon carbide, alumina, zirconia, or the like. The main component means such a component that makes up 80 mass % or more of the ceramic.

The substrate 11 may include a placement portion R1 on which electronic elements are placed on the first surface S1. The electronic elements may be placed on the placement portion R1 (see FIG. 1A) via a plate-shaped submount.

The wiring conductor 15 may include a linear conductor 15a positioned on the first surface S1. The linear conductor 15a extends in a single direction along the first surface S1. Although it is not illustrated, the wiring conductor 15 may include one or a plurality of conductors selected from the group consisting of a film-shaped conductor positioned on the first surface S1, a linear conductor positioned on the second surface S2, the film-shaped conductor positioned on the second surface S2, a via conductor positioned in the substrate 11, a linear conductor, and a film-shaped conductor. The wiring conductor 15 may function as a conductor that allows a voltage such as a power source voltage, a ground voltage, or a detection voltage or a signal such as a radio-frequency signal to be conducted therethrough.

As illustrated in FIG. 1B, the substrate 11 includes first layer particles 21 and second layer particles 22. The first layer particles 21 are positioned on a surface layer on the first surface S1 side. The second layer particles 22 are adjacent to the first layer particles 21 on the second surface S2 side. The ceramic is configured by sintering and closely aggregated a plurality of particles. Each of the first layer particles 21 and the second layer particles 22 correspond to an individual particle included in the ceramic.

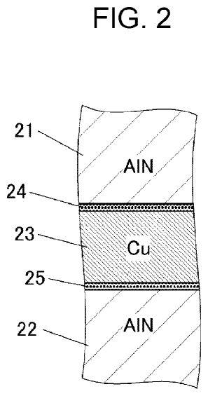

FIG. 2 is a diagram illustrating an interlayer structure between a first layer particle and a second layer particle.

The substrate 11 may include a metal layer 23 positioned at least between the first layer particles 21 and the second layer particles 22. The metal layer 23 may be positioned on the first surface S1 side of the first layer particles 21 or the second surface S2 side of the second layer particles 22. Furthermore, the metal layer 23 may be positioned between a pair of the first layer particles 21 adjacent to each other in a planar direction or between a pair of the second layer particles 22 adjacent to each other in the planar direction.

The metal layer 23 may include Cu (copper) as a main component. The metal layer 23 may have a higher thermal conductive property than that of element particles of the substrate 11.

The substrate 11 may include a first adhesion layer 24 and a second adhesion layer 25. The first adhesion layer 24 is positioned between the metal layer 23 and the first layer particles 21 and in contact with the metal layer 23 and the first layer particles 21. The second adhesion layer 25 is positioned between the metal layer 23 and the second layer particles 22 and in contact with the metal layer 23 and the second layer particles 22. Referring to FIGS. 1B and 1C, the first adhesion layer 24 and the second adhesion layer 25 are indicated by bold lines.

The first adhesion layer 24 and the second adhesion layer 25 may include TiO₂ (titanium oxide) as a main component. The first adhesion layer 24 produces an effect of reducing peeling of the first layer particles 21 and the metal layer 23 off from each other. The second adhesion layer 25 produces an effect of reducing peeling of the second layer particles 22 and the metal layer 23 off from each other.

With the above-described configuration, a coupling force between the first layer particles 21 and the second layer particles 22 increases due to the first adhesion layer 24, the metal layer 23, and the second adhesion layer 25. This can reduce the likelihood of dropping of the first layer particles 21 from the substrate 11. Furthermore, since a gap between the first layer particles 21 and the second layer particles 22 is filled with the metal layer 23, the thermal conductivity between the first layer particles 21 and the second layer particles 22 increases. This can improve a thermal dissipation property from the first surface S1 to the second surface S2 side in the substrate 11.

### <Details of Disposition of Metal Layer>

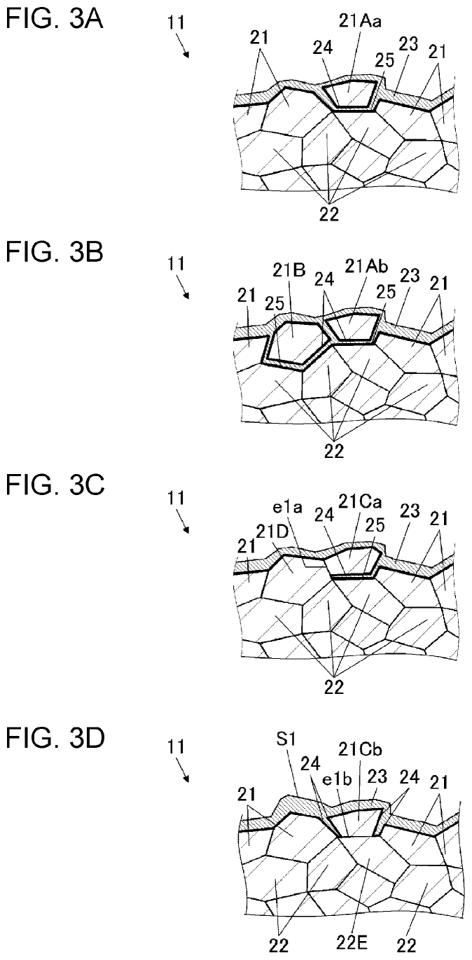

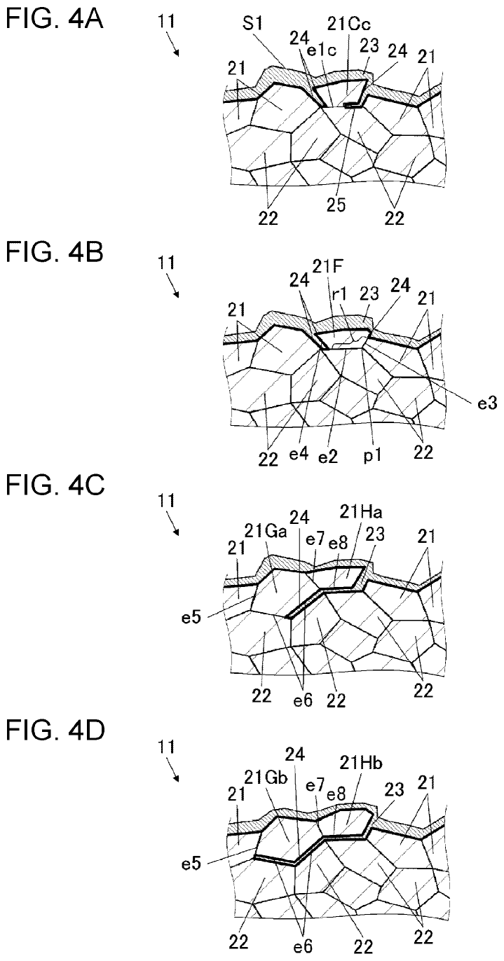

FIGS. 3A to 3D are respective longitudinal sectional views of a first example to fourth example, each illustrating disposition of the first layer particles and the metal layer. FIGS. 4A to 4D are respective longitudinal sectional views of a fifth example to eighth example, each indicating disposition of the first layer particles and the metal layer.

A periphery of each element particle of the substrate 11 is a polygonal shape in section. The element particles include the first layer particles 21 and the second layer particles 22. The periphery of the element particle becomes a polygonal shape in section because of close aggregation of the particles when the substrate 11 is sintered. Examples of the polygonal shape include not only an exact polygon but also shapes resembling a polygon such as a shape including slightly rounded corners and a shape including a small bend or a small step in a side thereof. Hereinafter, a portion of the polygonal shape able to be regarded as a single line except for a small bend or a small step is referred to as a “single side”. Furthermore, a portion on the second surface S2 side from the first surface S1 is defined as a lower portion, and a level direction along the first surface S1 is defined as a horizontal direction. When a side is positioned in the lower portion and inclined within ±45° relative to the horizontal direction, this side is referred to as a lower side. When a side is positioned in a side portion and inclined within ±45° relative to a vertical direction, this side is referred to as a vertical side. The longitudinal section means a section perpendicular to the first surface S1.

Many of the first layer particles 21 may be coupled to the second layer particles 22 partially without the metal layer 23 interposed therebetween. This coupling may occur when the ceramic is sintered. This configuration can reduce the likelihood of dropping of the first layer particles 21 from the substrate 11 even when the metal layer 23 is removed later by an etching process.

As illustrated in FIGS. 3A and 3B, in the longitudinal section of the substrate 11, the first layer particles 21 may include first particles 21Aa and 21Ab entire peripheries of which are surrounded by the first adhesion layer 24 and the metal layer 23. With this configuration, high coupling strength can be obtained between the first particle 21Aa and the second layer particles 22 and between the first particle 21Ab and the second layer particles 22. This can further reduce the likelihood of dropping of the first particles 21Aa and 21Ab from the substrate 11. Furthermore, when the first particles 21Aa and 21Ab are surrounded by the metal layer 23, the thermal conductivity is improved around the first particles 21Aa and 21Ab, and, in addition, an effect of diffusing heat in the horizontal direction is enhanced. This can improve the thermal dissipation property from the first surface S1 to the second surface S2 side via the substrate 11.

As illustrated in FIG. 3B, in the longitudinal section of the substrate 11, the first layer particles 21 may include a second particle 21B adjacent to the first particle 21Ab, and entire peripheries of the first particle 21Ab and the second particle 21B are surrounded by the metal layer 23 and the first adhesion layer 24. When a plurality of particles are continuously surrounded by the metal layer 23 and the first adhesion layer 24 as described above, coupling strength between the first layer particles 21 and the second layer particles 22 is further improved. This can further reduce the likelihood of dropping of the first layer particles 21 from the substrate 11. Furthermore, the thermal conductivity is further improved around the first particle 21Ab and the second particle 21B, and, in addition, the effect of diffusing the heat in the horizontal direction is further enhanced. This can further improve the thermal dissipation property from the first surface S1 to the second surface S2 side via the substrate 11.

As illustrated in FIGS. 3C, 3D, and 4A, in the longitudinal section of the substrate 11, the first layer particles 21 may include third particles 21Ca to 21Cc. Peripheries of the third particles 21Ca to 21Cc except for first sides e1a to e1c are covered with the metal layer 23 and the first adhesion layer 24. Also with this configuration, high coupling strength of the third particles 21Ca to 21Cc can be obtained. This can reduce the likelihood of dropping of the third particles 21Ca to 21Cc from the substrate 11.

As illustrated in FIG. 3C, the above-described first side e1a may be a first vertical side of the third particle 21Ca. With this configuration, a lower side of the third particle 21Ca is covered with the metal layer 23 and the first adhesion layer 24. Thus, the effect of diffusing the heat in the horizontal direction is enhanced around the third particle 21Ca. This can improve the thermal dissipation property from the first surface S1 to the second surface S2 side via the substrate 11.

As illustrated in FIGS. 3D and 4A, the above-described first sides e1b and e1c may be lower sides of the third particles 21Cb and 21Cc. With this configuration, both vertical sides of each of the third particles 21Cb and 21Cc are covered with the metal layer 23 and the first adhesion layer 24. Thus, the thermal conductivity from the first surface S1 to the second surface S2 side can be increased around the third particles 21Cb and 21Cc. This can improve the thermal dissipation property from the first surface S1 to the second surface S2 side via the substrate 11.

As illustrated in FIGS. 3D and 4A, in each of the third particles 21Cb and 21Cc, the distance between vertical sides may increase toward the first surface S1. With this configuration, even if the strength is unlikely to be ensured in a structure without the metal layer 23, high coupling strength of the third particles 21Cb and 21Cc can be obtained in this structure.

As illustrated in FIGS. 3C and 3D, in the longitudinal section of the substrate 11, the third particles 21Ca and 21Cb may be coupled to respective adjacent particles (for example, a fourth particle 21D included in the first layer particles 21 and a fifth particle 22E included in the second layer particles 22) via the first sides e1a and e1b. This configuration can reduce the likelihood of dropping of the third particles 21Ca and 21Cb from the substrate 11 even when the metal layer 23 is removed later by the etching process.

As illustrated in FIG. 4A, in the longitudinal section of the substrate 11, part of the first side e1c of the third particle 21Cc may be covered with the metal layer 23 and the first adhesion layer 24, and another part of the first side e1c of the third particle 21Cc may be coupled to an adjacent particle (for example, a first layer particle 21 or a second layer particle 22) without the metal layer 23 or the first adhesion layer 24 interposed between the third particle 21Cc and the adjacent particle. Although the first side e1c is the lower side of the third particle 21Cc in the example illustrated in FIG. 4A, the first side e1c may be a vertical side of the third particle 21Cc. With this configuration, a range of the metal layer 23 couple to the third particle 21Cc increases. Thus, the thermal conductivity around the third particle 21Cc can increase. This can improve the thermal dissipation property from the first surface S1 to the second surface S2 side via the substrate 11.

As illustrated in FIG. 4B, in the longitudinal section of the substrate 11, the first layer particles 21 may include a sixth particle 21F surrounded by the metal layer 23 and the first adhesion layer 24 except for a first region r1 that, out of two sides e2 and e3 adjacent to each other with a first corner portion p1 formed therebetween, includes the first corner portion p1 and continuously extends. Furthermore, the first region r1 of the sixth particle 21F may be coupled to adjacent particles (for example, one or both of a first layer particle 21 and a second layer particle 22) without the metal layer 23 or the first adhesion layer 24 interposed therebetween. Also with this configuration, when the metal layer 23 and the first adhesion layer 24 are positioned on sides not in contact with the first corner portion p1, coupling strength of the sixth particle 21F increases. This can reduce the likelihood of dropping of the sixth particle 21F from the substrate 11. Furthermore, the thermal conductivity around the sixth particle 21F can be increased, and the thermal dissipation property from the first surface S1 to the second surface S2 side via the substrate 11 can be improved.

The first region r1 may include a lower side of the sixth particle 21F. Furthermore, one of vertical sides e4 of the sixth particle 21F may be covered with the metal layer 23 and the first adhesion layer 24. This configuration can also increase the thermal conductivity in a path from the first surface S1 to the second surface S2 side around the sixth particle 21F. This can improve the thermal dissipation property from the first surface S1 to the second surface S2 side via the substrate 11.

As illustrated in FIGS. 4C and 4D, in the longitudinal section of the substrate 11, the first layer particles 21 may include the following seventh particles 21Ga and 21Gb. The seventh particles 21Ga and 21Gb each has a periphery including a lower side e6, a first vertical side e5, and a second vertical side e7 opposite from the first vertical side e5. The first vertical side e5 and the second vertical side e7 are coupled to first layer particles 21 respectively adjacent to the first vertical side e5 and the second vertical side e7 without the metal layer 23 or the first adhesion layer 24 interposed therebetween. The entirety or part of the lower side e6 is covered with the metal layer 23 and the first adhesion layer 24. With this configuration, high coupling strength can be obtained between the seventh particle 21Ga and the second layer particle 22 and between the seventh particle 21Gb the second layer particle 22. This can further reduce the likelihood of dropping of the seventh particles 21Ga and 21Gb from the substrate 11. Furthermore, with the above-described configuration, an effect of diffusing heat, via the metal layer 23, in the horizontal direction can be obtained. This can improve the thermal dissipation property from the first surface S1 to the second surface S2 side via the substrate 11. The above-described effect is further enhanced when the entirety of the lower side e6 is covered with the metal layer 23 and the first adhesion layer 24 as described in FIG. 4D.

Furthermore, as illustrated in FIGS. 4C and 4D, the first layer particles 21 may include the following eighth particles 21Ha and 21Hb respectively adjacent to the seventh particles 21Ga and 21Gb. Lower sides e8 of the eighth particles 21Ha and 21Hb are covered with the metal layer 23 and the first adhesion layer 24. The metal layer 23 and the first adhesion layer 24 at the lower sides e8 are continuous with the metal layer 23 and the first adhesion layer 24 that cover the lower sides e6 of the seventh particles 21Ga and 21Gb. With this configuration, high coupling strength can be obtained between the eighth particle 21Ha and the second layer particle 22 and between the eighth particle 21Hb and the second layer particle 22. This can further reduce the likelihood of dropping of the eighth particles 21Ha and 21Hb from the substrate 11. Furthermore, in the above-described configuration, the continuous metal layer 23 is positioned below the seventh particles 21Ga and 21Gb and the eighth particles 21Ha and 21Hb. Thus, the effect of diffusing the heat in the horizontal direction is enhanced around metal layer 23. This can further improve the thermal dissipation property from the first surface S1 to the second surface S2 side via the substrate 11.

### <Relationship Between Wiring Conductor and Metal Layer>

In a case to be described below, two wiring conductors 15 (corresponding to a first conductor and a second conductor) are positioned on the substrate 11 as illustrated in FIG. 1C. As has been described, the first adhesion layer 24, the metal layer 23, and the second adhesion layer 25 may be positioned between the first layer particles 21 and the second layer particles 22 below the two wiring conductors 15. Furthermore, the metal layer 23 positioned above the first layer particles 21 may be coupled to the wiring conductors 15.

In contrast, in a region R11 between a pair of adjacent wiring conductors 15 or a regions R12 and R13 around the wiring conductors 15, the first adhesion layer 24, the metal layer 23, or the second adhesion layer 25 in not necessarily positioned between the first layer particles 21 and the second layer particles 22. That is, the regions R11 to R13 may include dividing portions W of the first adhesion layer 24, the metal layer 23, and the second adhesion layer 25. Such a configuration can ensure high isolation of each wiring conductors 15.

### <Manufacturing Method>

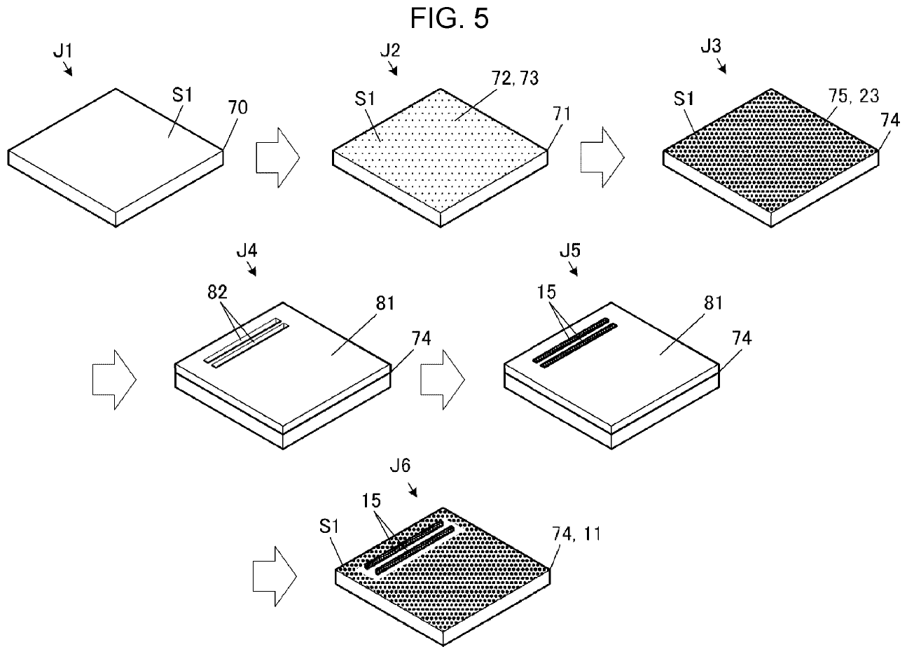

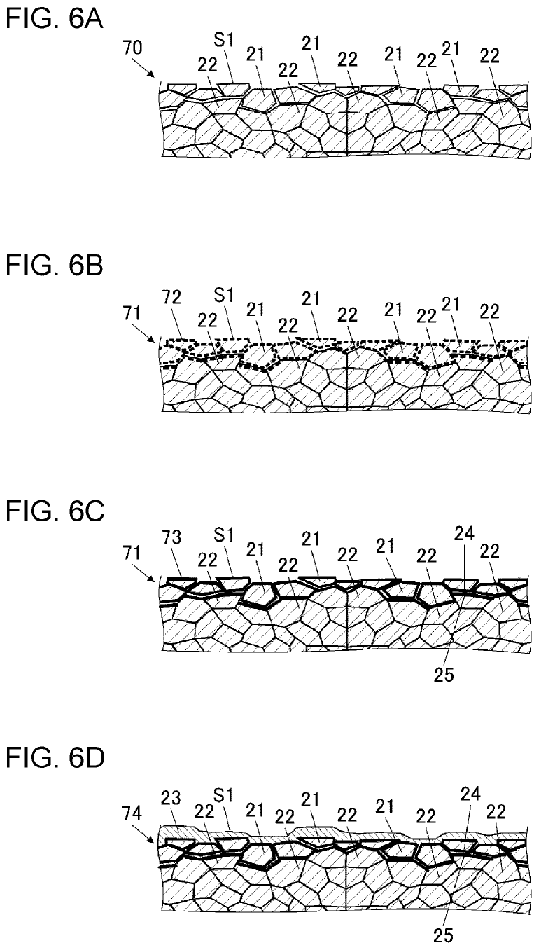

FIG. 5 is a diagram illustrating a manufacturing method for the wiring board according to the embodiment. FIGS. 6A to 6F are diagrams illustrating states around the first layer particles and the second layer particles in manufacturing steps as follows: FIG. 6A illustrates a state after a polishing step; FIG. 6B illustrates a state of a former stage of a Ti film forming step; FIG. 6C illustrates a state after the Ti film forming step; FIG. 6D illustrates a state after an electroless plating and sintering step; FIG. 6E illustrates a state after removal of a resist; and FIG. 6F illustrates a state after an etching step.

In the present embodiment, the manufacturing method for the wiring board 10 includes, sequentially in time, a polishing step J1, a Ti film forming step J2, an electroless plating and sintering step J3, a resist processing step J4, an electrolytic plating step J5, and a resist removal and etching step J6.

In the polishing step J1, the first surface S1 side of a sintered ceramic substrate 70 is polished with a polishing device. Depending on setting of operation parameters of the polishing device and parameters of a polishing agent, as illustrated in FIG. 6A, the first surface S1 can be flattened, and gaps such as microcracks can be formed between a plurality of first layer particles 21 (that is, in particle boundaries) and between the first layer particles 21 and the second layer particles 22 (that is, in particle boundaries). In the polishing step J1, to reduce the likelihood of dropping of the first layer particles 21, the above-described parameters may be set so as to maintain a subset of the particle boundaries between the first layer particles 21 and the surrounding particles.

In the Ti film forming step J2, first, a ceramic substrate 71 having been polished is immersed in a solution 72 of an organic titanium compound. As a result, as illustrated in FIG. 6B, the above-described solution 72 adheres to a top surface of the first surface S1 and enters the gaps formed in the polishing step J1. In FIG. 6B, the solution 72 is indicated by broken lines. Then, the ceramic substrate 71 to which the solution 72 adheres is sintered in an oxidizing atmosphere. Sintering may be performed under, for example, the following conditions; equal to or higher than 400° C. and equal to or longer than 30 minutes. When sintered, as illustrated in FIG. 6C, the solution 72 having entered the top surface of the first surface S1 and the above-described gaps is solidified and changed into a titanium oxide layer 73. In FIG. 6C, the titanium oxide layer 73 is indicated by bold lines. A subset of the titanium oxide layer 73 positioned between the first layer particles 21 and the second layer particles 22 correspond to the first adhesion layer 24 and the second adhesion layer 25. The Ti film forming step J2 may be a step of creating the titanium oxide layer 73 by a sol-gel process as described above.

In the electroless plating and sintering step J3, electroless Cu plating is performed on the first surface S1 side of a ceramic substrate 74. The electroless Cu plating is also performed on the gaps formed in the polishing step J1. Then, a sintering process is performed to diffuse elements at interfaces. The conditions of the sintering process may be as follows: the sintering is performed in an inert gas atmosphere at higher than or equal to 300° C. for longer than or equal to 30 minutes. As illustrated in FIG. 6D, due to the electroless Cu plating and the sintering step J3, the metal layer 23 is formed on the first surface S1 side of the first layer particles 21, in the gaps between the first layer particles 21, and the gaps between the first layer particles 21 and the second layer particles 22. In addition, the metal layer 23, the first adhesion layer 24, and the second adhesion layer 25 adhere to each other due to diffusion of the elements at the interfaces.

In the resist processing step J4, a pattern 82 for the wiring conductors 15 is formed on the metal layer 23 of the first surface S1 through, for example, a DFR (dry film resist) 81.

In the electrolytic Cu plating step J5, electrolytic Cu plating is performed on the metal layer 23 of the first surface S1 with the pattern 82 of the DFR 81 so as to form the wiring conductors 15 having a predetermined thickness.

In the resist removal and etching step J6, at least the metal layer 23 and the titanium oxide layer (that is, the first adhesion layer 24 and the second adhesion layer 25) around the wiring conductors 15 as well as the DFR 81 are etched. As illustrated in FIGS. 6E and 6F, due to the etching, the metal layer 23, the first adhesion layer 24, and the second adhesion layer 25 around the wiring conductors 15 are removed, thereby to ensure isolation of the wiring conductors 15.

After the etching, a plating step to perform electrolytic Ni (nickel)/Pd (palladium)/Au (gold) plating may be performed on top surfaces of the wiring conductors 15. Furthermore, when the pattern of the wiring conductors 15 is not necessary, the resist processing step J4, the electrolytic plating step J5, and the resist removal and etching step J6 may be omitted.

In the present embodiment, the wiring board 10 can be manufactured by the manufacturing method as described above.

### (Electronic Device and Electronic Module)

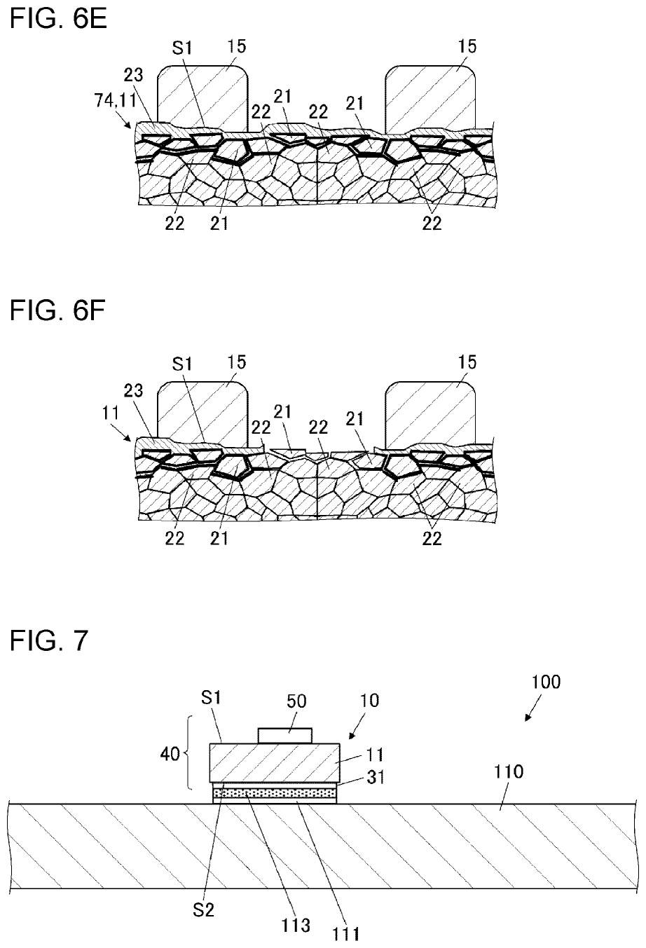

FIG. 7 is a diagram illustrating an electronic device and an electronic module according to the embodiment of the present disclosure.

In the present embodiment, an electronic element 50 is mounted on the wiring board 10 of the electronic device 40. Electrodes of the electronic element 50 may be electrically connected to the wiring conductors 15. The electronic device 40 may further include a package that accommodates the wiring board 10 and the electronic element 50.

As the electronic element 50, for example, any of the following various electronic components can be applied: an optical element such as an LD (laser diode), a PD (photo diode), and an LED (light emitting diode); an image capturing element of a CCD (charge coupled device) type, a CMOS (complementary metal oxide semiconductor) type, and the like; a piezoelectric resonator such as a quartz resonator; a semiconductor element such as a surface acoustic wave element, a semiconductor IC (integrated circuit), and the like; an electric capacitive element; an inductor element; and a resistor.

In the present embodiment, the electronic device 40 is mounted on a module board 110 of the electronic module 100. In addition to the electronic device 40, another electronic device, an electronic element, an electric element, and the like may be mounted on the module board 110. An electrode pad 111 may be provided on the module board 110, and the electronic device 40 may be joined to the electrode pad 111 via a joint 113 such as solder. An electrode 31 may be provided on the second surface S2 of the wiring board 10, and the electrode 31 may be joined to the electrode pad 111 via the joint 113.

With the electronic device 40 and the electronic module 100 according to the present embodiment, the electronic device 40 and the electronic module 100 that are highly reliable can be obtained by using the wiring board 10 that includes the robust surface layer of the substrate 11 and allows obtaining of the high thermal dissipation property from the first surface S1 to the second surface S2 side. In particular, since the robustness of the surface layer of the substrate 11 is realized below the wiring conductors 15 (see FIG. 1C) on the first surface S1, the likelihood of peeling off of the wiring conductors 15 can be reduced.

In the above description, the embodiment of the present disclosure has been described. However, in the present disclosure, the wiring board, the electronic device, or the electronic module is not limited to the above-described embodiment, and the details described in the embodiment can be appropriately changed without departing from the gist of the invention.

### INDUSTRIAL APPLICABILITY

The present disclosure can be utilized for a wiring board, an electronic device, and an electronic module.

### REFERENCE SIGNS

10 wiring board

11 substrate

S1 first surface

S2 second surface

15 wiring conductor

15a linear conductor

21 first layer particle

21Aa, 21Ab first particle

21B second particle

21Ca, 21Cb, 21Cc third particle

21D fourth particle

21F sixth particle

21Ga, 21Gb seventh particle

21Ha, 21Hb eighth particle

22 second layer particle

22E fifth particle

23 metal layer

24 first adhesion layer

25 second adhesion layer

e1a, e1b, e1c first side

p1 first corner portion

e2, e3 two adjacent sides

r1 first region

e4 vertical side

e5 first vertical side

e6, e8 lower side

e7 second vertical side

W dividing portion

40 electronic device

50 electronic element

100 electronic module

110 module board

1. A wiring board comprising:
a substrate including a first surface and a second surface positioned on an opposite side from the first surface,
wherein the substrate includes
a first layer particle positioned on a surface layer on a first surface side,
a second layer particle adjacent to the first layer particle on a second surface side,
a metal layer positioned at least between the first layer particle and the second layer particle,
a first adhesion layer positioned between the first layer particle and the metal layer and in contact with the first layer particle and the metal layer, and
a second adhesion layer positioned between the second layer particle and the metal layer and in contact with the second layer particle and the metal layer.

2. The wiring board according to claim 1,
wherein the first layer particle includes a first particle, and
wherein, in a longitudinal section, an entire periphery of the first particle is surrounded by the first adhesion layer and the metal layer.

3. The wiring board according to claim 2,
wherein the substrate includes a plurality of the first layer particles,
wherein the plurality of first layer particles further include a second particle adjacent to the first particle, and
wherein, in the longitudinal section, the entire periphery of the first particle and an entire periphery of the second particle are surrounded by the first adhesion layer and the metal layer.

4. The wiring board according to claim 1,
wherein the first layer particle includes a third particle, and
wherein, in a longitudinal section, the third particle except for a first side of a periphery of the third particle is surrounded by the metal layer and the first adhesion layer.

5. The wiring board according to claim 4,
wherein the substrate includes a plurality of the first layer particles,
wherein, in the longitudinal section, the periphery of the third particle includes a first vertical side, a lower side, and a second vertical side positioned opposite from the first vertical side,
wherein the first side is the first vertical side,
wherein the plurality of first layer particles include a fourth particle adjacent to the third particle, and
wherein, in the longitudinal section, the first vertical side is connected to the fourth particle without the metal layer or the first adhesion layer interposed between the first vertical side and the fourth particle.

6. The wiring board according to claim 4,
wherein, in the longitudinal section, the periphery of the third particle includes a first vertical side, a lower side, and a second vertical side positioned opposite from the first vertical side,
wherein the second layer particle includes a fifth particle adjacent to the third particle,
wherein the first side is the lower side, and
wherein, in the longitudinal section, the lower side is connected to the fifth particle without the metal layer or the first adhesion layer interposed between the lower side and the fifth particle.

7. The wiring board according to claim 6,
a distance between the first vertical side and the second vertical side increases toward the first surface.

8. The wiring board according to claim 4,
wherein a part of the first side is covered with the metal layer and the first adhesion layer, and a remaining part of the first side is connected to an adjacent particle without the metal layer or the first adhesion layer interposed between the remaining part of the first side and the adjacent particle.

9. The wiring board according to claim 1,
wherein the first layer particle includes a sixth particle that includes a periphery including a first corner portion and a plurality of sides in a longitudinal section,
wherein, in the longitudinal section, the sixth particle is surrounded by the metal layer and the first adhesion layer except for a first region that, out of two sides of the sixth particle adjacent to each other with a first corner portion formed between the two sides, includes the first corner portion and continuously extends, and
wherein the first region is connected to an adjacent particle without the metal layer or the first adhesion layer interposed between the first region and the adjacent particle.

10. The wiring board according to claim 9,
wherein, in the longitudinal section, the sixth particle includes a lower side, and
the first region includes the lower side.

11. The wiring board according to claim 1,
wherein the first layer particle includes a seventh particle that includes, in a longitudinal section, a periphery including a first vertical side, a lower side, a second vertical side positioned opposite from the first vertical side,
wherein, in the longitudinal section, the first vertical side of the seventh particle is connected to a particle adjacent to the first vertical side without the metal layer or the first adhesion layer interposed between the first vertical side and the particle adjacent to the first vertical side, and
the second vertical side of the seventh particle is connected to a particle adjacent to the second vertical side without the metal layer or the first adhesion layer interposed between the second vertical side and the particle adjacent to the second vertical side, and
wherein a part or an entirety of the lower side is covered with the metal layer and the first adhesion layer.

12. The wiring board according to claim 11,
wherein the substrate includes a plurality of the first layer particles,
wherein the plurality of first layer particles include an eighth particle adjacent to the seventh particle,
wherein, in the longitudinal section, a periphery of the eighth particle includes a first vertical side opposite to the seventh particle, a lower side, and a second vertical side positioned opposite from the first vertical side,
wherein the second vertical side and the lower side of the eighth particle are covered with the metal layer and the first adhesion layer, and
wherein the metal layer and the first adhesion layer covering the lower side of the eighth particle are continuous with the metal layer and the first adhesion layer covering the lower side of the seventh particle.

13. The wiring board according to claim 1, further comprising:
a first conductor and second conductor positioned on the first surface,
wherein, in a longitudinal section, dividing portions of the metal layer, the first adhesion layer, and the second adhesion layer are provided between the metal layer, the first adhesion layer, and the second adhesion layer that are positioned below the first conductor and the metal layer, the first adhesion layer, and the second adhesion layer that are positioned below the second conductor.

14. An electronic device comprising:
the wiring board according to claim 1; and
an electronic element placed on the wiring board.

15. An electronic module comprising:
the electronic device according to claim 14; and
a module board on which the electronic device is placed.
